(19) United States
(12) Patent Application Publication
(10) Pub. No.: US 2013/0134113 A1
(43) Pub. Date: May 30, 2013

(54) MOUNTING APPARATUS FOR EXPANSION CARD

(71) Applicants: CHAO-JIE CAI, Wuhan City (CN); YONG MA, Wuhan City (CN); YU-LAN LIU, Wuhan City (CN); YU-LIN LIU, Wuhan City (CN)

(72) Inventors: CHAO-JIE CAI, Wuhan City (CN); YONG MA, Wuhan City (CN); YU-LAN LIU, Wuhan City (CN); YU-LIN LIU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/557,286

(22) Filed: Jul. 25, 2012

(30) Foreign Application Priority Data
Nov. 24, 2011 (CN) 201110378332.X

(51) Int. Cl. H05K 7/14; H05K 7/18

(52) U.S. Cl. 211/26; 248/231.81

(57) ABSTRACT

A mounting apparatus includes a chassis; a mounting piece, a securing member, a mounting member, and a clipping member. The mounting piece is attached to a first end of an expansion card and secured to the chassis. The securing member is rotatably attached to the chassis and abutting the mounting piece. The mounting member is secured to the chassis and includes a securing rail and a resilient portion. The clipping member is attached to a second end of the expansion card and engaged with the securing rail. The resilient portion abuts the clipping member to prevent the clipping member from disengaging from the securing rail.

### BACKGROUND

1. Technical Field

The present disclosure relates to mounting apparatuses, and particularly to a mounting apparatus for securing expansion cards in an electronic device.

2. Description of Related Art

A computer system usually includes expansion cards, such as sound cards, video cards, graphics cards, etc., for enhancing the capabilities of the computer system. The expansion cards are often mounted to a computer casing of the computer system with screws. However, using screws to attach the expansion cards is laborious and time consuming.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus and an expansion card in accordance with an embodiment.

FIG. 2 is similar to FIG. 1, but viewed from a different aspect.

FIG. 3 is an isometric view of a mounting member of the mounting apparatus of FIG. 1.

FIG. 4 is similar to FIG. 3, but viewed from a different aspect.

FIG. 5 is an assembled view of the mounting apparatus of FIG. 1, and a securing member being located in a first position.

FIG. 6 is similar to FIG. 5, but viewed in a different aspect, and the securing member being located in a second position.

FIG. 7 is an enlarge view of a circled portion VII of FIG. 6.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

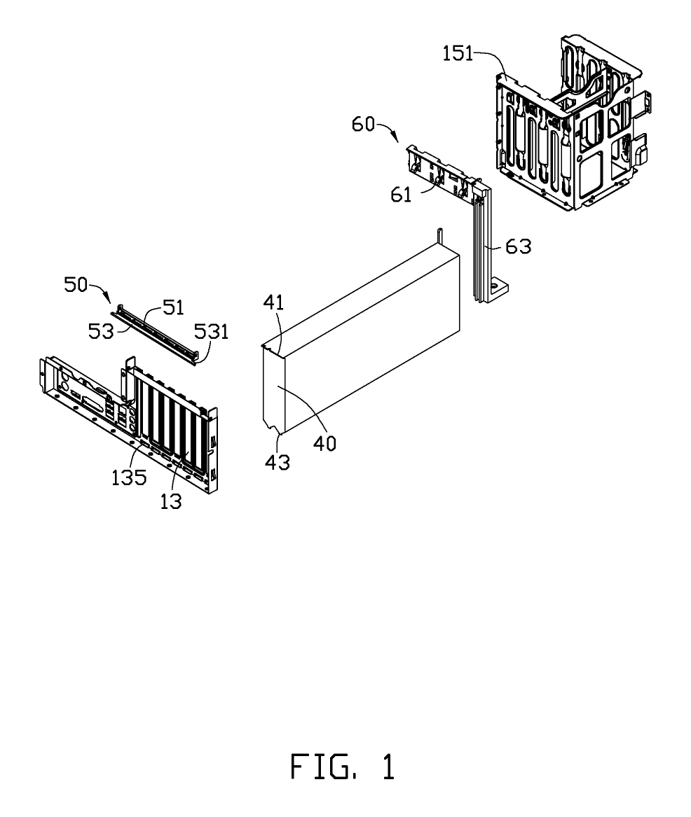

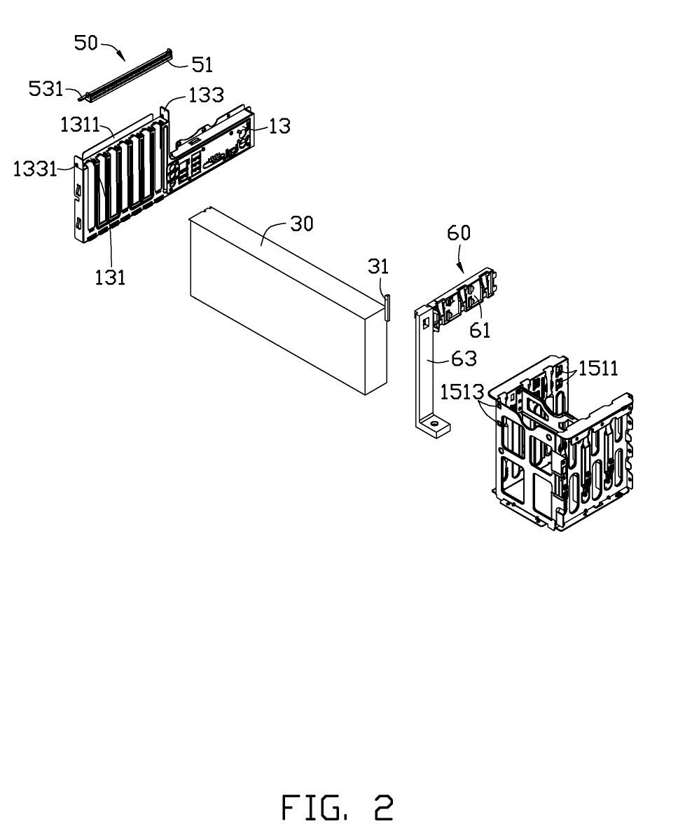

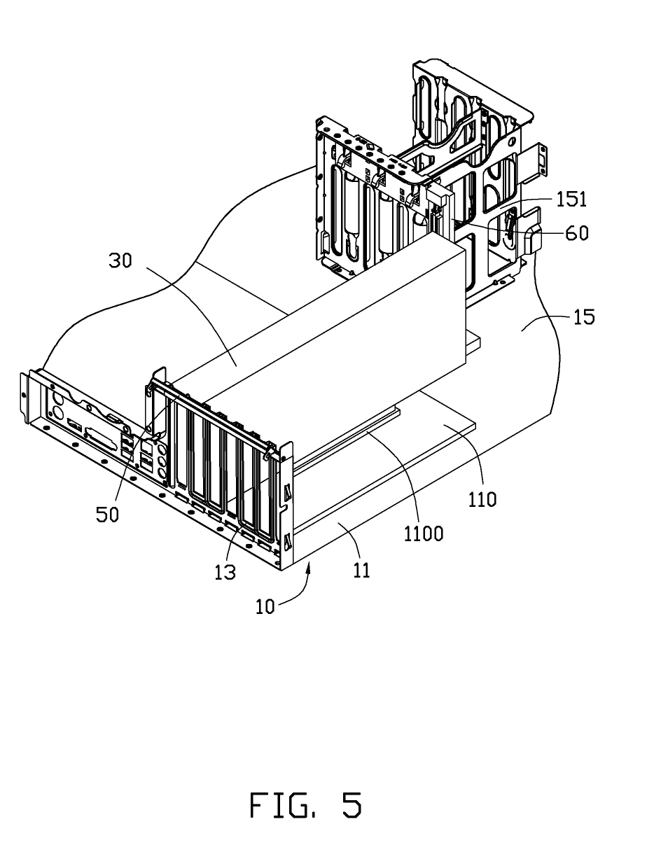

FIGS. 1 and 2, illustrate a mounting apparatus in accordance with an embodiment for securing an expansion card 30. The mounting apparatus includes a chassis 10 (see FIG. 5), a securing member 50, and a mounting member 60. The expansion card 30 may be, for example, one or more sound cards, video cards, or graphics cards, or other peripheral component interconnection cards.

FIGS. 1, 2, and 5, illustrate the chassis 10 in accordance with an embodiment. The chassis 10 includes a bottom plate 11, a front plate 13 connected to the bottom plate 11, and a rear plate 15. In one embodiment, the bottom plate 11 is substantially perpendicular to the front plate 13. A motherboard 110, with an expansion slot 1100, is attached to the bottom plate 11. A supporting piece 131 extends from the front plate 13, and two clipping pieces 133 extend upwardly from opposite sides of the supporting piece 131. Each of the two clipping pieces 133 defines a clipping hole 1331. A plurality of inserting slots 135 are defined in the bottom of the front plate 13. A tray 151 is attached to the rear plate 15. Two retaining holes 1511 are defined in a first panel of the tray 151, and two fixing holes 1513 are defined in a second panel substantially perpendicular to the first panel of the tray 151. In one embodiment, the tray 151 is configured for receiving storage devices.

A mounting piece 40 is attached to a front side of the expansion card 30, and a clipping member 31 is attached to a back side of the expansion card 30. An extending piece 41 extends from a first end of the mounting piece 40, and an inserting portion 43 extends from a second end of the mounting piece 40.

The securing member 50 includes a resisting panel 51 and a rotating shaft 53 connected to the resisting panel 51. Two rotating portions 531 extend from the rotating shaft 53.

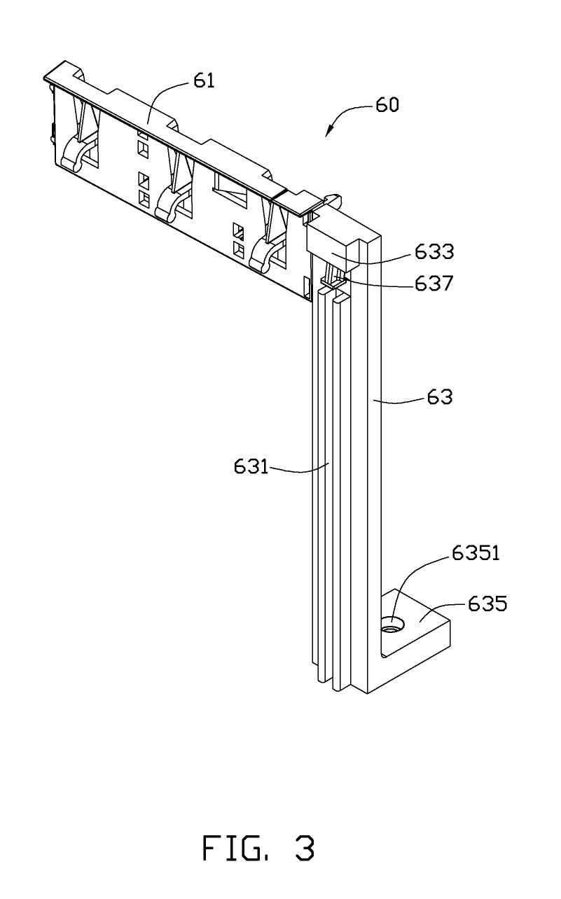

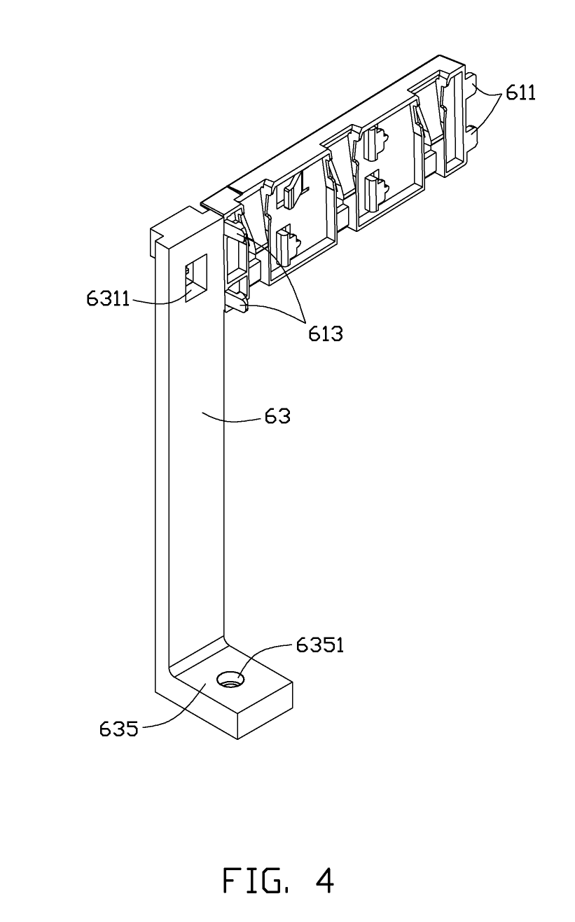

FIGS. 3 and 4, illustrate the mounting member 60 in accordance with an embodiment. The mounting member 60 includes a first portion 61, a second portion 635, and a connecting portion 63 connected to the first portion 61 and the second portion 635. In one embodiment, the connecting portion 63 is substantially perpendicular to the first portion 61 and the second portion 635, and the second portion 635 is substantially perpendicular to the first portion 61. Two elastic pieces 611 extend from a first end of the first portion 61, and two hooks 613 extend from a second end of the first portion 61 and adjacent to the connecting portion 63. In one embodiment, the two elastic pieces 611 and the first portion 61 are located on a same plane, and the two hooks 613 are substantially perpendicular to the first portion 61.

A fastening hole 6351 is defined in the second portion 635. A securing rail 631 extends from the connecting portion 63 and opposite to the two hooks 613. A block 633 extends from a top edge of the connecting portion 63, and a resilient portion 637 extends from the block 633 and towards the securing rail 631. In one embodiment, a top surface of the block 633 and a top surface of the connecting portion 63 are aligned on a common plane. A through hole 6311 is defined in the connecting portion 63 and on a back side of the block 633.

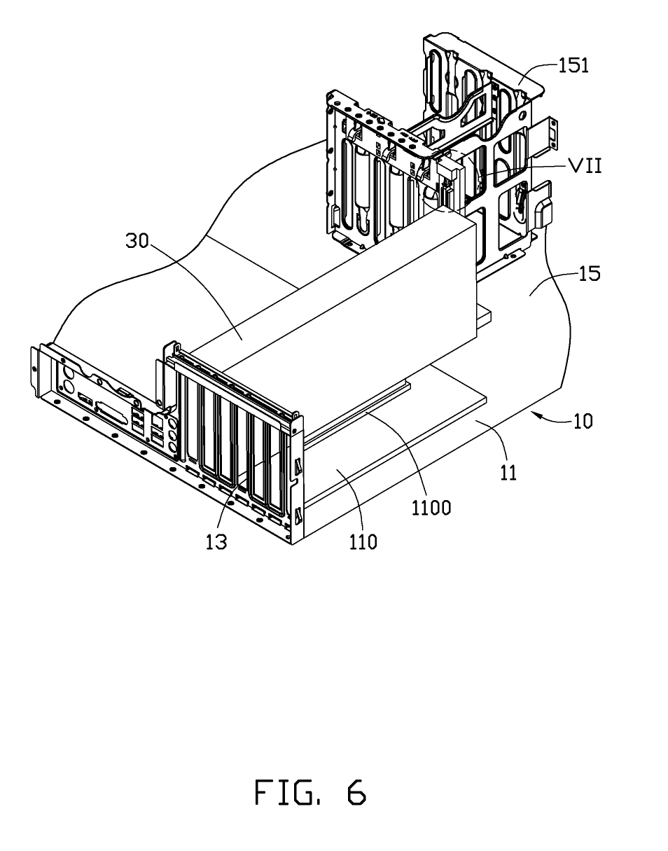

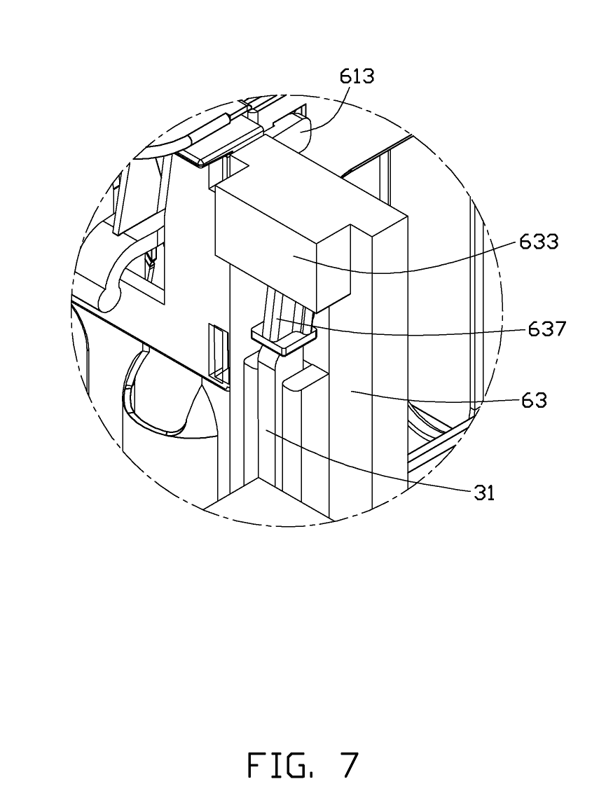

FIGS. 5-7, illustrate an assembly of the mounting apparatus in accordance with an embodiment. In assembly, the two elastic pieces 611 are engaged in the two retaining holes 1511, and the two hooks 613 are engaged in the fixing holes 1513. Thus, the mounting member 60 is secured to the tray 151. A fastener, (not shown) can receive in the fastening hole 6351 and a hole (not shown) of the bottom plate 11, to secure the mounting member 60 to the bottom plate 11.

The expansion card 30 is inserted into the expansion slot 1100. The extending piece 41 is clipped with the supporting piece 131, and the inserting portion 43 is engaged in the inserting slot 135. Simultaneously, the clipping member 31 urges the resilient portion 637 to deform towards the through hole 6311. When the clipping member 31 passes the resilient portion 637 and is received in the securing rail 631, the resilient portion 637 rebounds to abut the clipping member 31, for preventing the clipping member 31 from moving out of the securing rail 631.

The securing member 50 is attached to the front plate 13, and the two rotating portions 531 are engaged in the two clipping holes 1331. Thus, the securing member 50 is secured to the front plate 13. The securing member 50 is rotated to engage with the supporting piece 131 to abut the extending piece 41, and the extending piece 41 can be prevented from being moved by the securing member 50.

In disassembly, the resilient portion 637 is pressed towards the through hole 6311 to detach from the clipping member 31. The securing member 50 is rotated to remove the resisting panel 51 from the extending piece 41. The expansion card 30 is moved upwardly and can be disengaged from the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a chassis;
a mounting piece configured to be attached to a first end of an expansion card and secured to the chassis;
a securing member rotatably attached to the chassis and abutting the mounting piece;
a mounting member secured to the chassis and comprising a securing rail and a resilient portion; and
a clipping member attached to a second end of the expansion card;
wherein the clipping member is engaged with the securing rail, and the resilient portion abuts the clipping member to prevent the clipping member from disengaging from the securing rail.

2. The mounting apparatus of claim 1, wherein a through hole is defined in the mounting member, and the resilient portion is deformable to engage with the through hole.

3. The mounting apparatus of claim 1, wherein a block extends from the mounting member, and the resilient portion extends from the block and towards the securing rail.

4. The mounting apparatus of claim 3, wherein the mounting member comprises a connecting portion, the securing rail is locate on the connecting portion, and the block and the connecting portion are aligned on a common plane.

5. The mounting apparatus of claim 4, wherein a tray is received in the chassis, the mounting member further comprises a first portion substantially perpendicular to the connecting portion, and the first portion is secured to the tray.

6. The mounting apparatus of claim 5, wherein the first portion comprises an elastic piece received in a retaining hole of the tray and a hook received in a fixing hole of the tray, the elastic piece extends from the first portion and aligned on a same plane with the first portion, and the hook is substantially perpendicular to the first portion.

7. The mounting apparatus of claim 6, wherein the chassis comprises a bottom plate, the mounting member further comprises a second portion connected to the connecting portion, and the second portion is secured to the bottom plate.

8. The mounting apparatus of claim 7, wherein the second portion is substantially perpendicular to the first portion and the connecting portion.

9. The mounting apparatus of claim 1, wherein the clipping member extends from a top surface of the expansion card.

10. A mounting apparatus comprising:
a chassis comprises a bottom plate;
a tray received in the chassis;
a mounting piece configured to be attached to a first end of an expansion card and secured to the chassis;
a securing member rotatably attached to the chassis and abutting the mounting piece;
a mounting member comprising a connecting portion, a first portion extending in a first direction, and a second portion extending in a second direction substantially perpendicular to the first direction; the first portion secured to the tray, and the second portion secured to the bottom plate; a securing rail and a resilient portion located on the connecting portion; and
a clipping member attached to a second end of the expansion card and engaged with the securing rail;
wherein the resilient portion abuts the clipping member, and the resilient portion is deformable to disengage the clipping member from the securing rail.

11. The mounting apparatus of claim 10, wherein a through hole is defined in the mounting member, and the resilient portion is deformable to engaged in the through hole.

12. The mounting apparatus of claim 10, wherein a block extends from the mounting member, and the resilient portion extends from the block and towards the securing rail.

13. The mounting apparatus of claim 12, wherein the securing rail is located on the connecting portion, and the block and the connecting portion are aligned on a common plane.

14. The mounting apparatus of claim 13, wherein the first portion comprises an elastic piece received in a retaining hole of the tray and a hook received in a fixing hole of the tray, the elastic piece extends from the first portion and aligned on a same plane with the first portion, and the hook is substantially perpendicular to the first portion.

15. The mounting apparatus of claim 10, wherein the second portion is substantially perpendicular to the first portion and the connecting portion.

16. The mounting apparatus of claim 10, wherein the clipping member extends from a top surface of the expansion card.
